(19) United States
(12) Patent Application Publication
(10) Pub. No.: US 2011/0157834 A1
(43) Pub. Date: Jun. 30, 2011

(54) HEAT/ELECTRICITY DISCRETE METAL CORE-CHIP ON BOARD MODULE

(76) Inventor: HSIANG-HUA WANG, Taipei City (TW)

(21) Appl. No.: 12/898,723

(22) Filed: Oct. 6, 2010

(30) Foreign Application Priority Data
Dec. 25, 2009 (TW) 098144997

(51) Int. Cl. H05K 7/20; H01R 43/00

(52) U.S. Cl. 361/717; 29/829

(57) ABSTRACT

A heat/electricity discrete metal core-chip on board Module includes a heat dissipation substrate, which has a surface that is recessed to form a carriage zone and a relatively elevated engagement section; a dielectric layer, which is formed of a compound that is formed on the heat dissipation substrate through conversion coating and covers the carriage zone of the heat dissipation substrate, the dielectric layer defining a window like heat conduction zone at a location corresponding to the engagement section of the heat dissipation substrate, so that the heat conduction zone corresponds exactly to the engagement section of the heat dissipation substrate; and an electrical connection layer, which is formed on the dielectric layer. A chip is set on the heat conduction zone and is connected to the electrical connection layer through wire bonding, whereby the paths for heat transfer and electricity transmission are separated.

### (a) TECHNICAL FIELD OF THE INVENTION

The present invention generally relates to a heat/electricity discrete metal core-chip on board module, more particularly to a metal core-chip on board module for applications of light-emitting diode (LED) or the related technology, but not limited thereto.

### (b) DESCRIPTION OF THE PRIOR ART

A metal core-chip on board (MCCOB) Module is one of the most basic components of an electronic device. With the technology requirement for new application, the power consumption of chip mounted on a MCCOB is getting more and more seriously, as a result of which, the situation of heat from light emission is getting more and more commonly seen. Taking a light-emitting diode (LED) as an example, when a white LED for lighting purposes possesses a high power, the heat from light emission made by the LED is also high. The heat must be properly and efficiently dissipated to ensure operation safety and lifespan of the electronic product. FIG. 8 of the attached drawings shows a conventional MCCOB Module, which comprises a bottommost heat dissipation substrate 80 (which is often an aluminum board) and a dielectric layer 81 (which is often made of anodic aluminum oxide (AAO) is laminated on a surface of the heat dissipation substrate 80. The dielectric layer 81 is provided thereon with an electrical connection layer 82. The electrical connection layer 82 can be of a multi-layer structure of which an example comprises a first layer 821 (such as gold), a second layer 822 (such as nickel), and a third layer 823 (such as copper). On the electrical connection layer 82, an LED die or chip 83 is set and wire bonding 84 is formed to electrically connect to a circuit thereby forming a complete circuit structure. However, such an arrangement has drawbacks. For example, the chip 83 generates heat, which, as indicated by arrows, is transferred through the dielectric layer 81 to the metal heat dissipation substrate 80 for removal of the heat. The efficiency to release heat is slow. Further, the heat dissipation substrate 80 is not in direct engagement with the chip 83 and direct heat dissipation from the heat source of the chip 83 cannot be realized, whereby a great amount of residual heat remains in the board and the heat cannot be efficiently dissipated.

Referring to FIG. 9 of the attached drawings, another known MCCOB is shown, which comprises an aluminum substrate 91, a dielectric layer 90, and a copper foil 92 that are laminated. The aluminum substrate 91 provides a major function of heat dissipation. The dielectric layer 90 is often made of an organic compound for isolation purposes. The copper foil 92 carries thereon an electronic circuit including a chip (not shown). When the chip set on the copper foil 92 gives off heat, the heat must travel through the dielectric layer 90 that is of a predetermined thickness to reach the aluminum substrate 91 for heat dissipation. Apparently, the effect of heat dissipation is still poor, and this is one of the common drawbacks of this kind of structure.

Thus, the conventional MCCOB all show poor heat dissipation performance and external heat dissipation devices are needed. This requires additional space, resources and raises the costs.

### SUMMARY OF THE INVENTION

An objective of the present invention is to provide a heat/electricity discrete metal core-chip on board Module, which comprises:

a heat dissipation substrate, which has a surface that is recessed to form a carriage zone and a relatively elevated engagement section; a dielectric layer, which is formed of a compound that is formed on the heat dissipation substrate through conversion coating and covers the carriage zone of the heat dissipation substrate, the dielectric layer defining a window like heat conduction zone at a location corresponding to the engagement section of the heat dissipation substrate, so that the heat conduction zone corresponds exactly to the engagement section of the heat dissipation substrate; and an electrical connection layer, which is formed on the dielectric layer. As such, the chip is set on the heat conduction zone and is connected to the electrical connection layer through wire bonding, whereby the paths for heat transfer and electricity connection are separated and heat can be efficiently and directly transferred from the heat conduction zone to the heat dissipation substrate for releasing of the heat without causing any interference to the connection of electricity to the electronic components.

The foregoing objectives and summary provide only a brief introduction to the present invention. To fully appreciate these and other objects of the present invention as well as the invention itself, all of which will become apparent to those skilled in the art, the following detailed description of the invention and the claims should be read in conjunction with the accompanying drawings. Throughout the specification and drawings identical reference numerals refer to identical or similar parts.

Many other advantages and features of the present invention will become manifest to those versed in the art upon making reference to the detailed description and the accompanying sheets of drawings in which a preferred structural embodiment incorporating the principles of the present invention is shown by way of illustrative example.

### BRIEF DESCRIPTION OF THE DRAWINGS

FIG. 1 is a schematic view showing an example application of the present invention.

FIG. 2 is a schematic view showing a structure according to an embodiment of the present invention.

FIG. 3 is a schematic view showing a structure according to another embodiment of the present invention.

FIG. 4 is a schematic view showing a structure according to a further embodiment of the present invention.

FIG. 5 is a schematic view showing a structure according to yet a further embodiment of the present invention.

FIG. 6-1 shows a first drawing demonstrating a process for manufacturing the structure according to the present invention.

FIG. 6-2 shows a second drawing demonstrating the process for manufacturing the structure according to the present invention.

FIG. 6-3 shows a third drawing demonstrating the process for manufacturing the structure according to the present invention.

FIG. 6-4 shows a fourth drawing demonstrating the process for manufacturing the structure according to the present invention.

FIG. 6-5 shows a fifth drawing demonstrating the process for manufacturing the structure according to the present invention.

FIG. 6-6 shows a sixth drawing demonstrating the process for manufacturing the structure according to the present invention.

FIG. 6-7 shows a seventh drawing demonstrating the process for manufacturing the structure according to the present invention.

FIG. 7-1 shows a varied example of a process for manufacturing a structure according to the present invention.

FIG. 7-2 shows a varied example of a process for manufacturing a structure according to the present invention.

FIG. 8 is a schematic view showing a conventional structure of metal core-chip on board.

FIG. 9 is a schematic view showing another conventional structure of metal core-chip on board.

### DETAILED DESCRIPTION OF THE PREFERRED EMBODIMENTS

The following descriptions are exemplary embodiments only, and are not intended to limit the scope, applicability or configuration of the invention in any way. Rather, the following description provides a convenient illustration for implementing exemplary embodiments of the invention. Various changes to the described embodiments may be made in the function and arrangement of the elements described without departing from the scope of the invention as set forth in the appended claims.

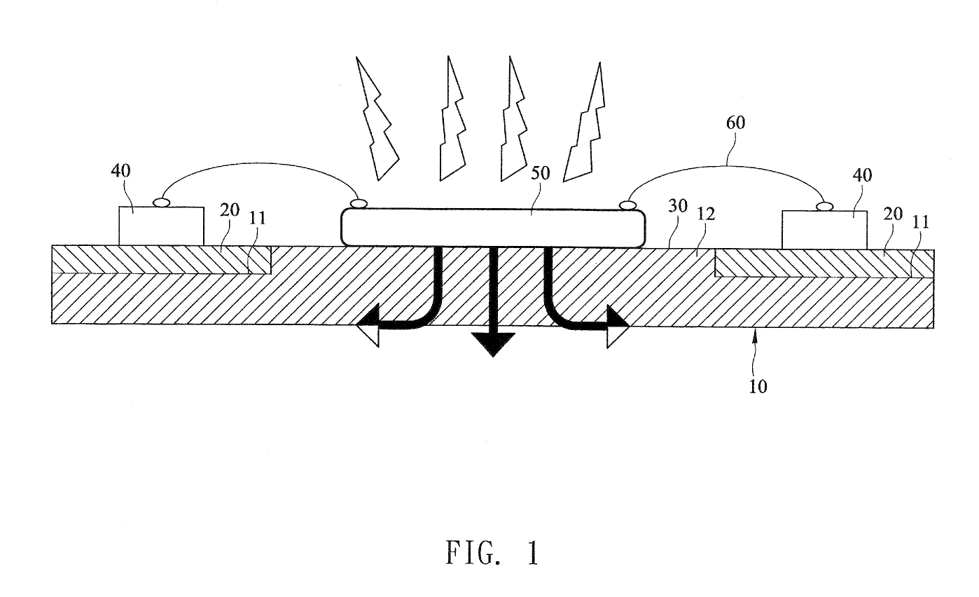

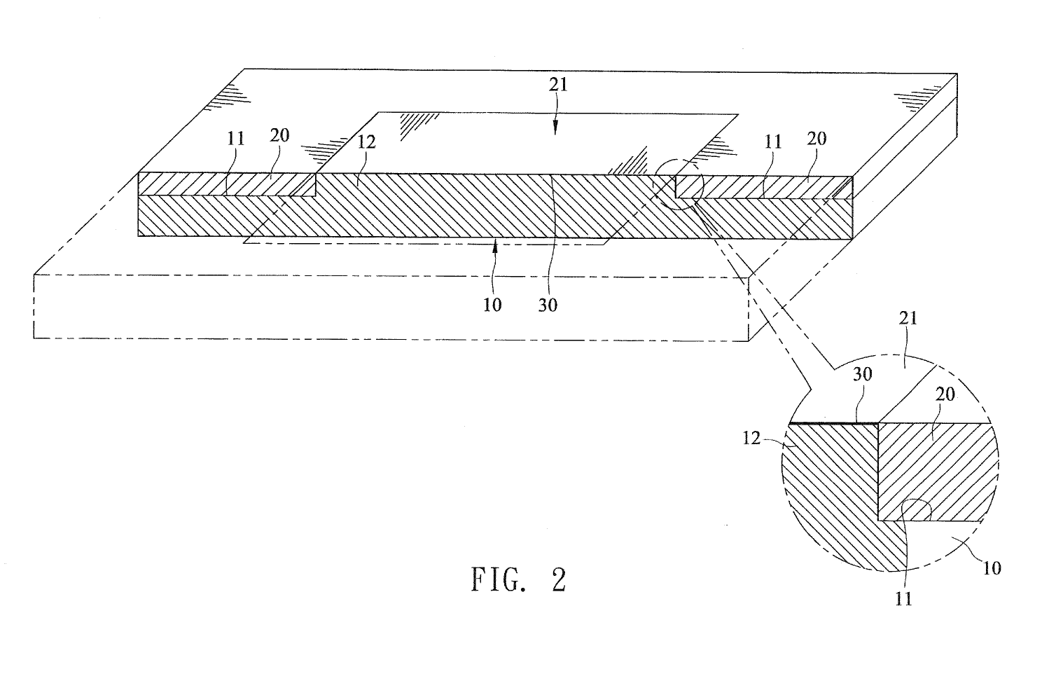

Referring to FIGS. 1 and 2, the present invention provides a MCCOB (Metal Core-Chip on Board) Module, comprising the following components:

A heat dissipation substrate 10 is preferably made of an aluminum-based substrate. The heat dissipation substrate 10 forms a recessed carriage zone 11 at a suitable location and a relatively elevated engagement section 12.

A dielectric layer 20 is coating on the carriage zone 11 of the heat dissipation substrate 10 and is made of a compound that is formed through conversion coating of the heat dissipation substrate 10 itself, such as aluminum oxides or aluminum compounds formed of other gases. The dielectric layer 20 forms a window zone in the area where the engagement section 12 of the heat dissipation substrate 10 is located to serve as a heat conduction zone 21.

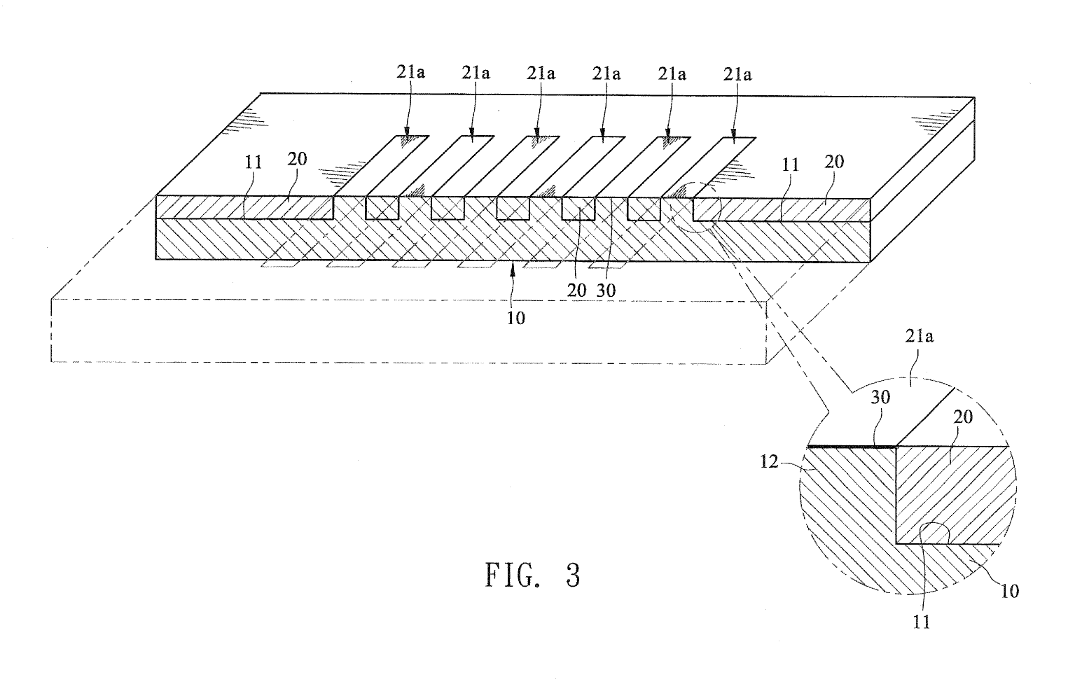

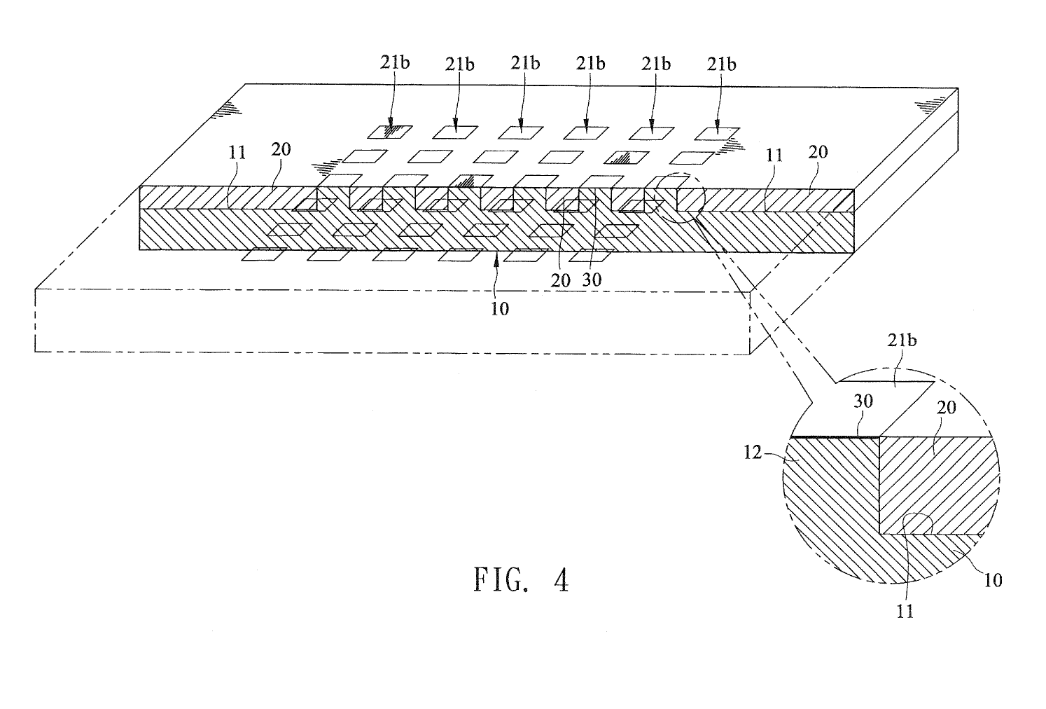

The heat conduction zone 21 is thus located exactly corresponding to the engagement section 12 of the heat dissipation substrate 10 and can be varied to any desired shape as required by practical applications. Several demonstrations of the variation of the shape of the heat conduction zone 21 will be given. FIG. 3 shows an example where multiple (or single) elongate strip like heat conduction zones 21a are provided. FIG. 4 shows an example where multiple (or single) square cell like or grating like heat conduction zones 21b are provided. These are some of the most commonly used example shapes. However, it is apparent that other arrangements or shapes are also feasible in view of the concept of the present invention.

Referring to FIGS. 1, 2, 3, and 4, a layer of heat conduction glue 30 is coated on the heat conduction zone(s) 21, 21a, 21b to support thereon a chip 50, as shown in FIG. 1.

Referring to FIG. 1, an electrical connection layer 40 is formed on the dielectric layer 20. In a case where the present invention is applied to light-emitting diode (LED), an LED chip or die 50 is set on the heat conduction glue 30 at the site of the heat conduction zone 21 and one or more bonding wires 60 are formed to electrically connect the electrical connection layer 40 so as to form a complete circuit structure. Thus, when the LED chip 50 emits light, heat generated thereby travels as indicated by the arrows in the drawing to directly penetrate through the heat conduction glue 30 to be absorbed by the heat dissipation substrate 10. This provides the MCCOB of the present invention an advantage of high efficiency of heat dissipation over the conventional MCCOB, and also increases the life spans of components, prevents the circuit from being influenced by the heat to ensure stability of quality.

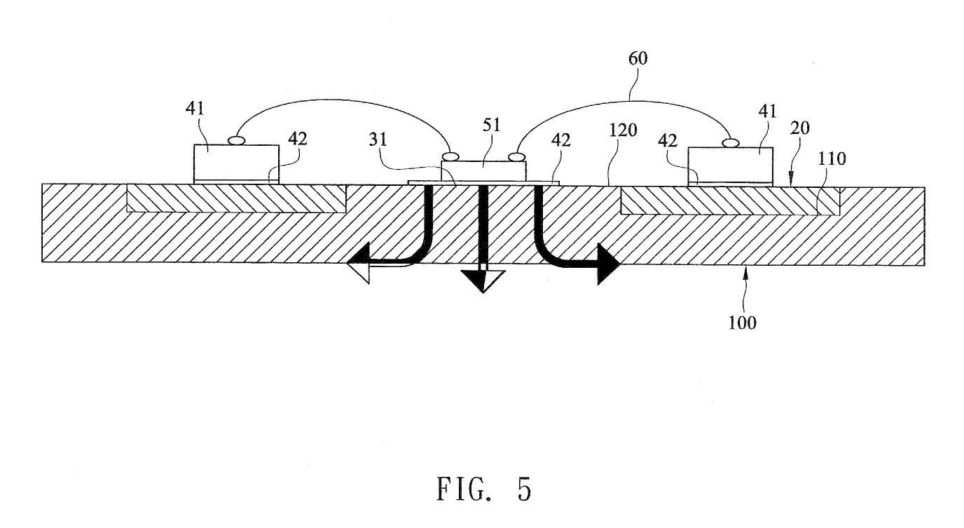

Referring to FIG. 5, another embodiment of the present invention is shown, wherein a heat dissipation substrate, which is designated now by reference numeral 100 for distinction, has a surface forming a plurality of recessed carriage zones 110, and a dielectric layer 20 is coated. In fact, the dielectric layer 20 is directly formed on the heat dissipation substrate 100 as a compound formed through conversion coating, such as aluminum oxides or aluminum compounds formed of other gases. The planar dielectric layer 20 and an engagement section 120 of the heat dissipation substrate 100 are provided, at suitable locations, with a sputtering layer 42. The sputtering layer 42 is preferably made of a copper based material. The sputtering layer 42 on the dielectric layer 20 is provided thereon with an electrical connection layer 41 on which a circuit is laid and the sputtering layer 42 on the engagement section 120 is coated with semiconductor heat conduction glue 31 on which a chip 51 is mounted and bonding wires 60 are formed. This also provides the same effect of efficient heat dissipation and separation of heat and electricity, whereby heat is transferred directly from the underside of the chip 51 to the dissipation substrate 100 without causing any influence to the circuit quality of the electrical connection layer 41.

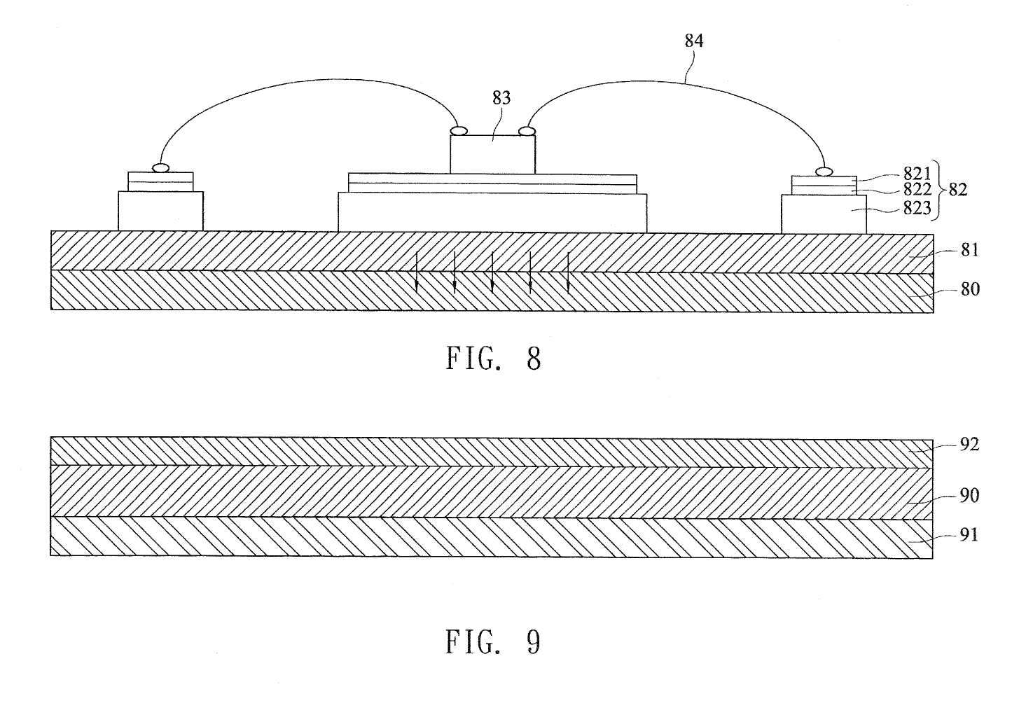

Thus, the features of the present invention as shown in FIGS. 1 and 5 allow the heat generated by a chip 50, 51 to be directly transferred to a heat dissipation substrate 10, 100, rather than making the heat passing through a dielectric layer 81, 90 to reach a heat dissipation substrate 80 or an aluminum substrate 91 as shown in the conventional technologies of FIGS. 8, 9. Apparently, the problem of poor heat dissipation of the conventional technologies is overcome by the present invention.

For a clear understanding of the present invention, a detailed description of an illustrative manufacturing process according to the present invention will be given, which process comprises the following steps:

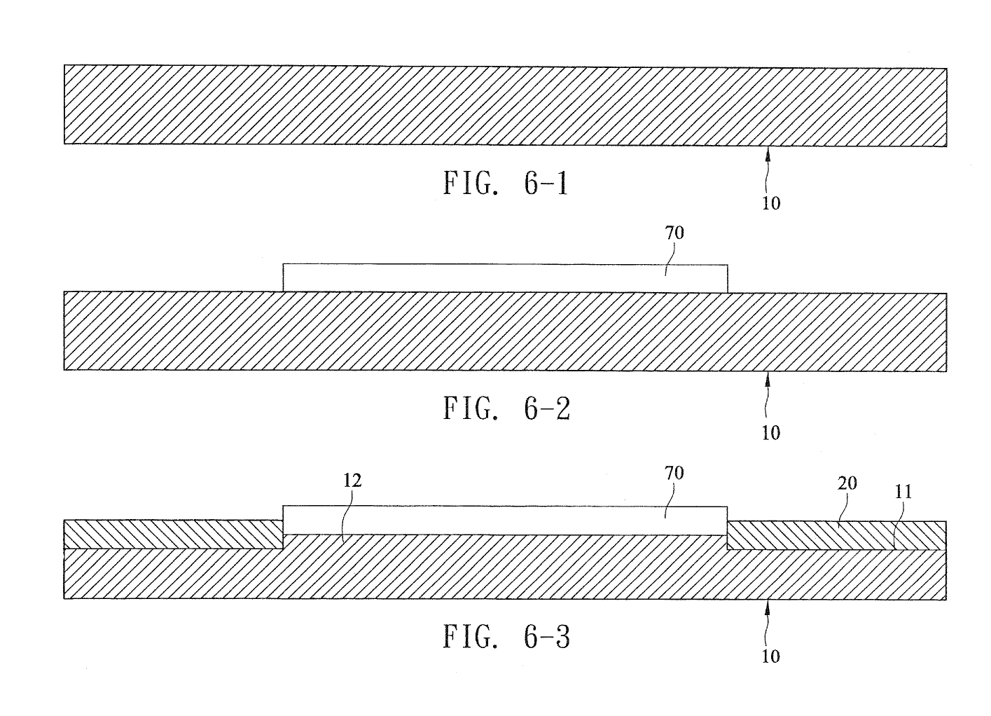

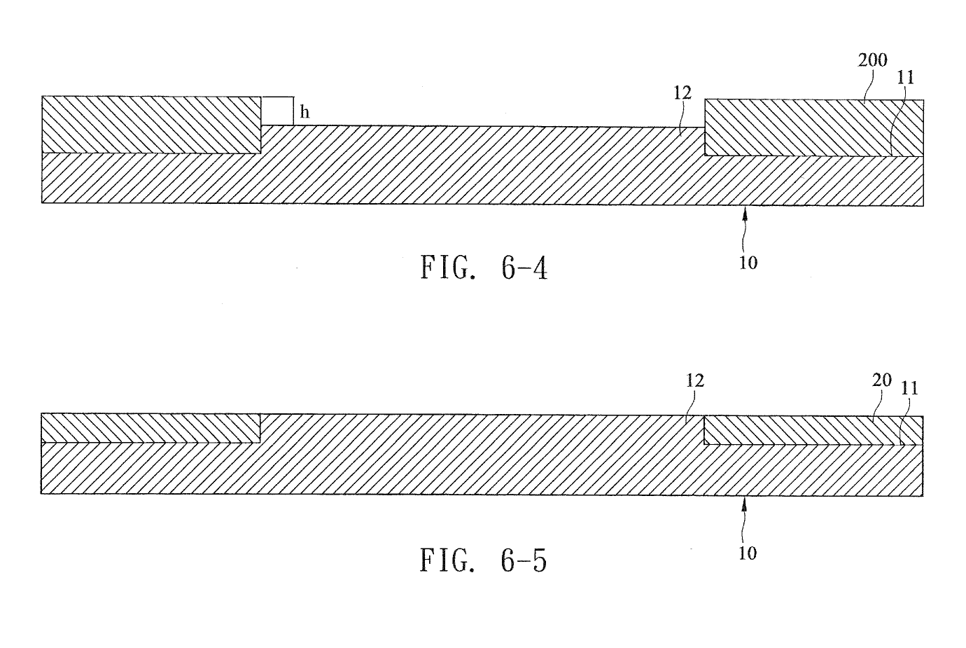

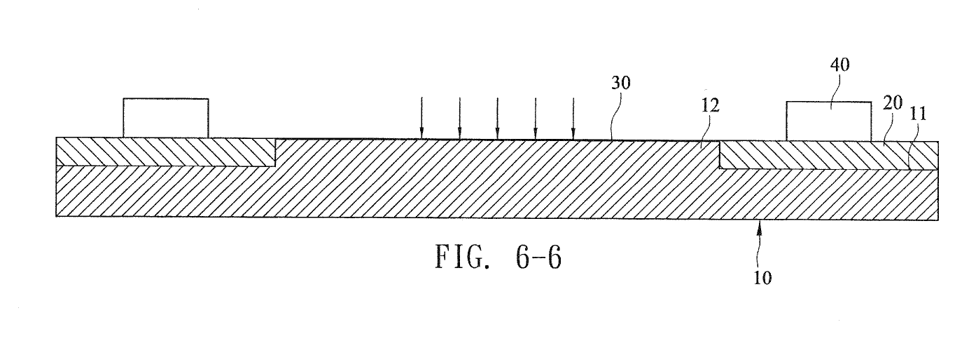

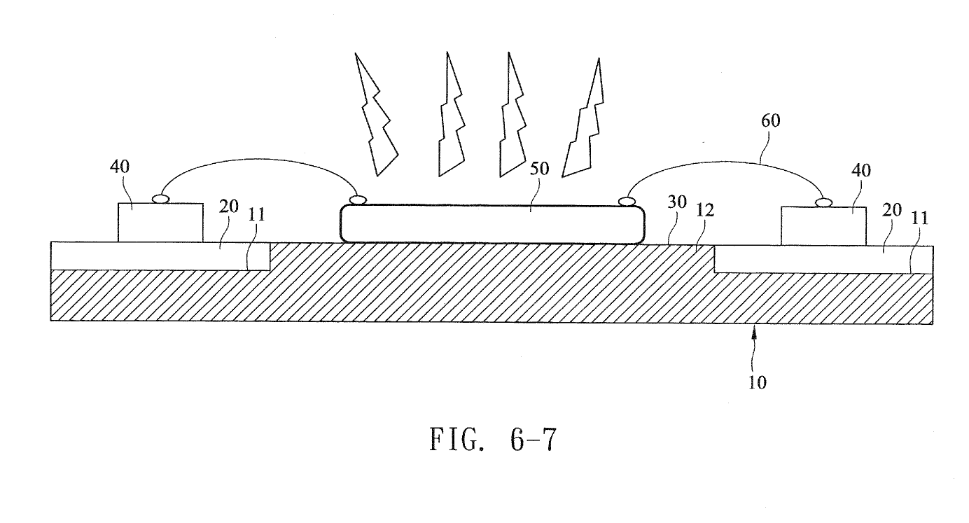

(1) Referring to FIG. 6-1, firstly, a heat dissipation substrate 10 is prepared by means of for example cutting, surface polishing, and cleaning. The heat dissipation substrate 10 is preferably an aluminum substrate.

(2) Referring to FIG. 6-2, a mask layer 70 is formed on predetermined locations of the heat dissipation substrate 10 by means of for example printed circuit technology.

(3) Referring to FIG. 6-3, portions of the heat dissipation substrate 10 where no mask layer 70 are formed are subjected to conversion coating to form a dielectric layer 20 of a predetermined depth. In the instant embodiment of the present invention, oxidation is used as an example, whereby the dielectric layer 20 is formed of anodic aluminum oxidation (AAO).

The dielectric layer 20 thus defines one or more heat conduction zones 21, 21a, 21b on the heat dissipation substrate 10, as shown in FIGS. 2, 3, and 4, for canying thereon one or more chips (not shown in the drawings).

The dielectric layer 20 is formed by corroding into the heat dissipation substrate 10 to form a carriage zone 11 and an engagement section 12 on a surface of the heat dissipation substrate 10, and further, the dielectric layer 20, when being formed, is bulged upward to form the raised engagement section 12.

(4) Referring to FIGS. 6-3 and 6-4, the mask layer 70 is removed to expose the dielectric layer 20 and the engagement section 12, which has a difference (H) in height. Alternatively, they can be ground and polished for planarization to form a continuous planar surface, as shown in FIG. 6-5.

(5) Referring to FIG. 6-6, an electrical connection layer 40 is laid on the dielectric layer 20 with the following steps:

(5-1) forming a plurality of electrical connection layers with polarization or chemical coating;

(5-2) coating a mask layer on predetermined electrical connection portions with circuit printing technology; and

(5-3) removing non electrical connection portions through etching.

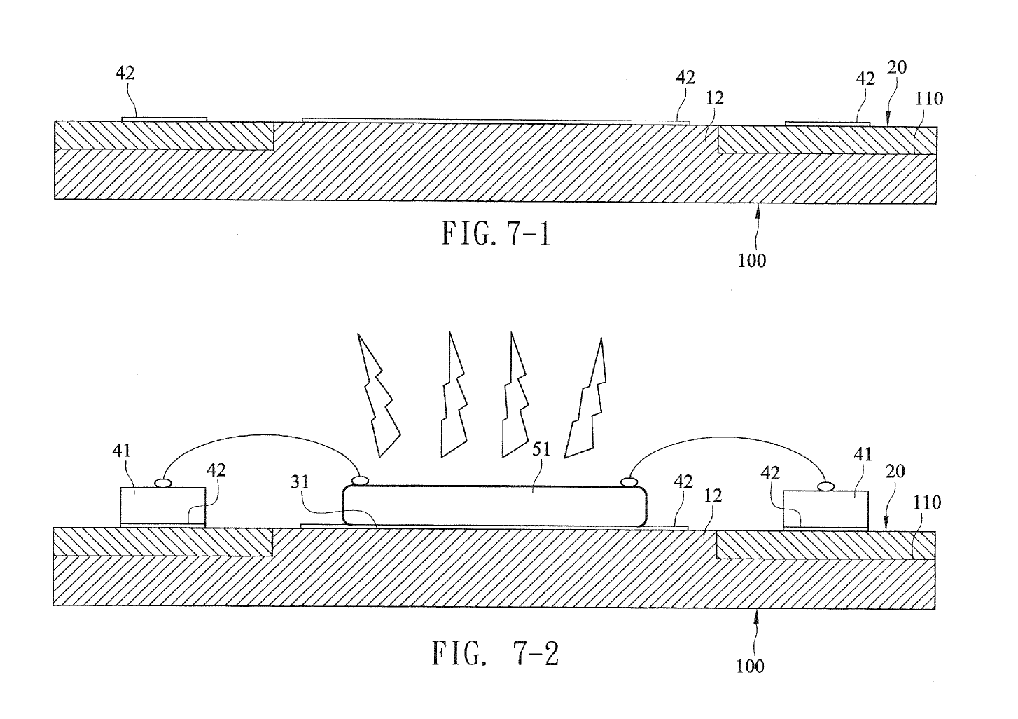

Referring to FIG. 6-7, an LED chip 50 is set on conduction glue 30 coated on the engagement section 12 of the heat dissipation substrate 10 and bonding wires 60 are formed to connect to the electrical connection layer 40 to form a complete circuit structure, whereby when the LED chip 50 is energized to give off light, the chip generates heat that is transferred as indicated by the arrows of FIG. 1 directly through the semiconductor heat conduction glue 30 to be absorbed by the heat dissipation substrate 10.

In case that the surface of the heat dissipation substrate 10 is made planar by grinding and polishing as shown in FIG. 6-5, in a different embodiment, as shown in FIGS. 7-1 and 7-2, a sputtering layer 42 is formed first, and then the electrical connection layer 41 is formed, followed by setting of the chip 51 and forming of the bonding wires to complete the structure. Heat from the chip 51 can be transferred directly downward to the heat dissipation substrate 100.

Thus, the present invention provides enhanced effect of heat dissipation and therefore extends the life span of electronic components so that it offers an excellent industrial value.

While certain novel features of this invention have been shown and described and are pointed out in the annexed claim, it is not intended to be limited to the details above, since it will be understood that various omissions, modifications, substitutions and changes in the forms and details of the device illustrated and in its operation can be made by those skilled in the art without departing in any way from the spirit of the present invention.

I claim:

1. A heat/electricity discrete metal core-chip on board Module, comprising:
a heat dissipation substrate, which has a surface that is recessed to form a carriage zone and a relatively elevated engagement section;
a dielectric layer, which is formed of a compound that is formed on the heat dissipation substrate through conversion coating and covers the carriage zone of the heat dissipation substrate, the dielectric layer defining a window like heat conduction zone at a location corresponding to the engagement section of the heat dissipation substrate, so that the heat conduction zone corresponds exactly to the engagement section of the heat dissipation substrate; and
an electrical connection layer, which is formed on the dielectric layer.

2. The heat/electricity discrete metal core-chip on board Module according to claim 1, wherein the heat dissipation substrate comprises an aluminum substrate.

3. The heat/electricity discrete metal core-chip on board Module according to claim 1, wherein the dielectric layer defines multiple heat conduction zones.

4. The heat/electricity discrete metal core-chip on board Module according to claim 1, wherein the heat conduction zone is an elongate strip.

5. The heat/electricity discrete metal core-chip on board Module according to claim 1, wherein the heat conduction zone is square.

6. The heat/electricity discrete metal core-chip on board Module according to claim 1, wherein the engagement section of the heat dissipation substrate is coated with semiconductor heat conduction glue in the heat conduction zone.

7. The heat/electricity discrete metal core-chip on board Module according to claim 1, wherein the heat conduction zone carries a chip.

8. The heat/electricity discrete metal core-chip on board Module according to claim 1, wherein the engagement section is coated with a sputtering layer.

9. The heat/electricity discrete metal core-chip on board Module according to claim 1, wherein a sputtering layer is formed between the dielectric layer and the electrical connection layer.

10. The heat/electricity discrete metal core-chip on board Module according to claim 1, wherein the heat conduction zone of the heat dissipation substrate has a predetermined shape.

11. A method for manufacturing a heat/electricity discrete metal core-chip on board Module, comprising the following steps:
(1) preparing a metal heat dissipation substrate, the heat dissipation substrate having a portion coated with a mask layer;
(2) subjecting a portion of the heat dissipation substrate where no mask layer is coated to conversion coating to form a dielectric layer of a predetermined depth with the dielectric layer delimiting at least one heat conduction zone on the heat dissipation substrate for carrying a chip; the heat dissipation substrate forming an engagement section corresponding to the heat conduction zone;
(3) removing the mask layer and planarizing a surface of the heat dissipation substrate;
(4) coating heat conduction glue on the engagement section of the heat dissipation substrate and forming an electrical connection layer on the dielectric layer; and
(5) setting a chip on the heat conduction glue of the engagement sections and forming wire bonding with the electrical connection layer so as to transfer heat and electricity through separate path.

12. The method according to claim 11, wherein the dielectric layer comprises anodic aluminum oxide.

13. The method according to claim 11, wherein after planarizing the surface of the heat dissipation substrate of step (3), a step of forming a sputtering layer is included.
